(19) United States
(12) Patent Application Publication
(10) Pub. No.: US 2024/0282600 A1
(43) Pub. Date: Aug. 22, 2024

(54) LIGHT IRRADIATION TYPE HEAT TREATMENT METHOD AND HEAT TREATMENT APPARATUS

(71) Applicant: SCREEN Holdings Co., Ltd., Kyoto (JP)

(72) Inventor: Oma NAKAJIMA, Kyoto-shi (JP)

(21) Appl. No.: 18/524,684

(22) Filed: Nov. 30, 2023

(30) Foreign Application Priority Data
Feb. 16, 2023 (JP) 2023-022145

(51) Int. Cl. H01L 21/67; H01L 21/687

(52) U.S. Cl. CPC H01L 21/67115; H01L 21/67248; H01L 21/68707

(57) ABSTRACT

A preceding wafer is heat-treated in a treatment chamber. After the completion of the heat treatment, a gate valve is opened, and the preceding wafer is transported out of the treatment chamber. Thereafter, there is a wait of a predetermined time period, with the gate valve closed and halogen lamps on. Light irradiation from the halogen lamps prevents the temperature in the treatment chamber from decreasing during the waiting period. After the waiting period, the halogen lamps turn off, and the gate valve is opened. Then, a succeeding wafer is transported into the treatment chamber. After the gate valve is closed again, the succeeding wafer is heat-treated. The provision of the waiting period makes the treatment conditions of semiconductor wafers uniform even if the transport time of the semiconductor wafers is prolonged.

### BACKGROUND OF THE INVENTION

### Field of the Invention

The present invention relates to a heat treatment method and a heat treatment apparatus which irradiate a substrate with light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

U.S. Patent Application Publication No. 2020/0243357 discloses a heat treatment apparatus which irradiates a semiconductor wafer received in a chamber with light from halogen lamps to preheat the semiconductor wafer, and thereafter irradiates a front surface of the semiconductor wafer with flashes of light. It is also disclosed in U.S. Patent Application Publication No. 2020/0243357 that one hand of a transport robot is used to take a preceding semiconductor wafer subjected to heating treatment out of the chamber, and the other hand of the transport robot is used to transport an untreated semiconductor wafer into the chamber, whereby wafer exchange is performed.

To ensure the wafer exchange, it is necessary that, when the treatment of the preceding semiconductor wafer is completed, the transport robot holds a succeeding semiconductor wafer and waits in front of the chamber. To this end, the treatment time of a recipe has been conventionally adjusted so that the treatment in the chamber is the rate-determining step in a procedure for a series of processes of semiconductor wafers. In other words, the adjustment has been made so that the treatment time in the chamber is longer than the time required for the semiconductor wafer taken out of a carrier (or cassette) to be transported to the chamber. This ensures the wafer exchange, and as a result causes a semiconductor wafer to be constantly present in the chamber, thereby stabilizing the temperature in the chamber.

Unfortunately, adding a new processing unit to the transport path of semiconductor wafers increases the transport time of the semiconductor wafers from the carrier to the chamber. In such a case, a state in which the treatment in the chamber is the rate-determining step (referred to hereinafter as “chamber rate-determining”) is disturbed, and there are cases in which the wafer exchange cannot be performed, resulting in the occurrence of a time period during which no semiconductor wafer is present in the chamber. When no semiconductor wafer is present in the chamber, heating is not performed by the halogen lamps and flash lamps. The longer the time period during which no semiconductor wafer is present in the chamber is, the lower the temperature of the chamber becomes. As a result, this causes different chamber temperatures for multiple semiconductor wafers constituting a lot to thereby give rise to non-uniform treatment results among the multiple semiconductor wafers.

Returning to the state of chamber rate-determining can be done by extending the treatment time of the recipe. It is, however, not easy to change the conditions of a production recipe that has been determined after a large number of evaluations.

### SUMMARY

The present invention is intended for a method of heating a substrate by irradiating the substrate with light.

According to one aspect of the present invention, the method comprises the steps of: (a) irradiating a first substrate held by a susceptor in a chamber with light from a lamp to heat the first substrate; (b) transporting the first substrate out of the chamber by means of a transport robot, the step (b) being executed after the completion of the step (a); (c) waiting for a predetermined time period, with no substrate present in the chamber, the step (c) being executed after the step (b); (d) transporting a second substrate into the chamber by means of the transport robot; and (e) irradiating the second substrate held by the susceptor in the chamber with light from the lamp to heat the second substrate.

The treatment conditions of the substrates are made uniform even if the transport time of the substrates is prolonged.

Preferably, an atmosphere in the chamber is heated by the light irradiation from the lamp in the step (c).

The temperature in the chamber during the waiting period is prevented from decreasing. This makes the treatment conditions of the substrates more uniform.

The present invention is also intended for a heat treatment apparatus for heating a substrate by irradiating the substrate with light.

According to one aspect of the present invention, the heat treatment apparatus comprises: a chamber for receiving a substrate therein; a susceptor for holding the substrate in the chamber; a lamp for irradiating the substrate held by the susceptor with light; a transport robot for transporting the substrate into and out of the chamber; and a controller for controlling the lamp and the transport robot, wherein the controller controls the transport robot so that, after the transport robot transports a first substrate subjected to heating treatment by the light irradiation from the lamp out of the chamber, the transport robot waits for a predetermined time period, with no substrate present in the chamber, and then transports a second substrate into the chamber.

The treatment conditions of the substrates are made uniform even if the transport time of the substrates is prolonged.

Preferably, the lamp heats an atmosphere in the chamber by the light irradiation during the waiting period, with no substrate present in the chamber.

The temperature in the chamber during the waiting period is prevented from decreasing. This makes the treatment conditions of the substrates more uniform.

It is therefore an object of the present invention to make the treatment conditions of substrates uniform.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a heat treatment apparatus according to the present invention;

FIG. 2 is a front view of the heat treatment apparatus of FIG. 1:

FIG. 3 is a longitudinal sectional view showing a configuration of a heat treatment part;

FIG. 4 is a perspective view showing the entire external appearance of a holder;

FIG. 5 is a plan view of a susceptor;

FIG. 6 is a sectional view of the susceptor;

FIG. 7 is a plan view of a transfer mechanism;

FIG. 8 is a side view of the transfer mechanism;

FIG. 9 is a plan view showing an arrangement of halogen lamps;

FIG. 10 is a flow diagram showing a procedure for wafer exchange in a first preferred embodiment;

FIG. 11 is a timing diagram of the wafer exchange; and

FIG. 12 is a flow diagram showing a procedure for the wafer exchange in a second preferred embodiment.

### DESCRIPTION OF THE PREFERRED EMBODIMENTS

Preferred embodiments according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

### First Preferred Embodiment

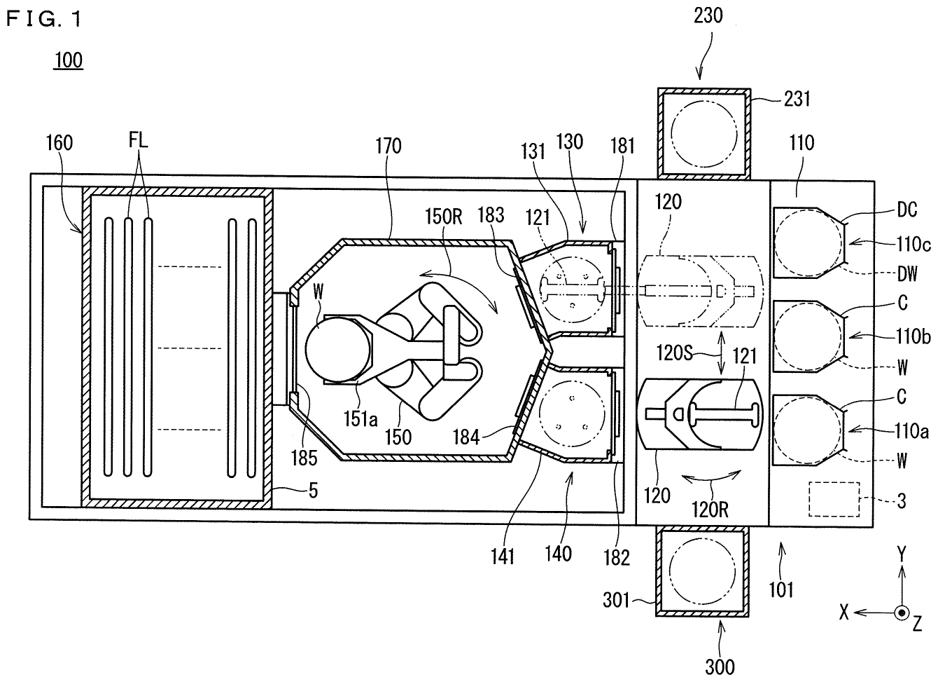

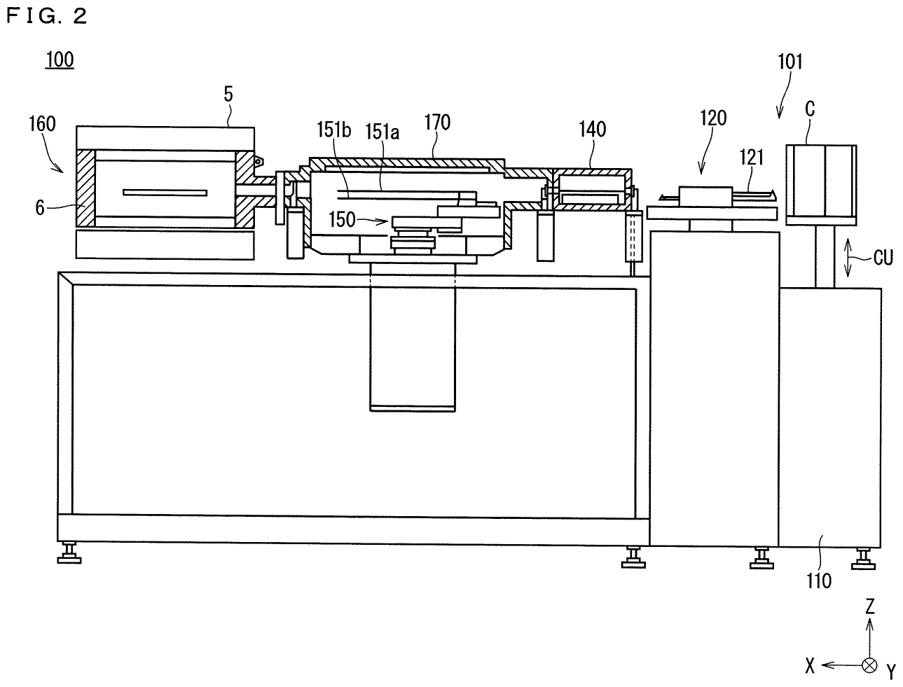

First, a heat treatment apparatus according to the present invention will be described. FIG. 1 is a plan view of a heat treatment apparatus 100 according to the present invention, and FIG. 2 is a front view of the heat treatment apparatus 100. The heat treatment apparatus 100 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding. An XYZ rectangular coordinate system in which an XY plane is defined as a horizontal plane and a Z axis is defined to extend in a vertical direction is additionally shown in FIGS. 1 to 3 for purposes of clarifying the directional relationship therebetween.

As shown in FIGS. 1 and 2, the heat treatment apparatus 100 includes: an indexer part 101 for transporting untreated semiconductor wafers W from the outside into the heat treatment apparatus 100 and for transporting treated semiconductor wafers W to the outside of the heat treatment apparatus 100; an alignment part 230 for positioning an untreated semiconductor wafer W; a flaw detection part 300 for detecting the presence or absence of flaws in a back surface of a semiconductor wafer W; two cooling parts 130 and 140 for cooling semiconductor wafers W subjected to the heating treatment; a heat treatment part 160 for performing flash heating treatment on a semiconductor wafer W; and a transport robot 150 for transferring a semiconductor wafer W to and from the cooling parts 130 and 140 and the heat treatment part 160. The heat treatment apparatus 100 further includes a controller 3 for controlling operating mechanisms provided in the aforementioned processing parts and the transport robot 150 to cause the flash heating treatment of the semiconductor wafer W to proceed.

The indexer part 101 includes: a load port 110 for placing thereon a plurality of carriers (or cassettes) C arranged in juxtaposition; and a transfer robot 120 for taking an untreated semiconductor wafer W out of each of the carriers C and for storing a treated semiconductor wafer W into each of the carriers C. To be precise, the indexer part 101 includes three load ports, and the load port 110 is a collective designation for a first load port 110a, a second load port 110b, and a third load port 110c. (The three load ports 110a, 110b, and 110c are collectively referred to as the load port 110, unless otherwise identified.) Carriers C in which semiconductor wafers W (also referred to as product wafers W) that become products are stored are placed on the first load port 110a and the second load port 110b. On the other hand, the third load port 110c is a load port exclusive to a dummy carrier DC in which dummy wafers DW are stored. That is, only the dummy carrier DC is placed on the third load port 110c. Typically, the dummy carrier DC containing the dummy wafers DW is always placed on the third load port 110c.

An unmanned transport vehicle (an AGV (automatic guided vehicle) or an OHT (overhead hoist transfer)) or the like transports a carrier C with untreated semiconductor wafers W stored therein and the dummy carrier DC to place the carrier C and the dummy carrier DC on the load port 110. The unmanned transport vehicle also carries a carrier C with treated semiconductor wafers W stored therein and the dummy carrier DC away from the load port 110.

In the load port 110, the carriers C and the dummy carrier DC are movable upwardly and downwardly as indicated by an arrow CU in FIG. 2 so that the transfer robot 120 is able to load any semiconductor wafer W (or any dummy wafer DW) into each of the carriers C and the dummy carrier DC and unload any semiconductor wafer W (or any dummy wafer DW) from each of the carriers C and the dummy carrier DC. The carriers C and the dummy carrier DC may be of the following types: an SMIF (standard mechanical interface) pod and an OC (open cassette) which exposes stored semiconductor wafer W to the outside atmosphere, in addition to a FOUP (front opening unified pod) which stores semiconductor wafer W in an enclosed or sealed space.

The transfer robot 120 is slidable as indicated by an arrow 120S in FIG. 1, pivotable as indicated by an arrow 120R in FIG. 1, and movable upwardly and downwardly. Thus, the transfer robot 120 loads and unloads semiconductor wafers W into and from the carriers C and the dummy carrier DC, and transfers semiconductor wafers W to and from the alignment part 230, the flaw detection part 300, and the two cooling parts 130 and 140. The operation of the transfer robot 120 loading and unloading the semiconductor wafers W into and from the carriers C (or the dummy carrier DC) is achieved by the sliding movement of a hand 121 of the transfer robot 120 and the upward and downward movement of the carriers C. The transfer of the semiconductor wafers W between the transfer robot 120 and the alignment part 230, between the transfer robot 120 and the flaw detection part 300, or between the transfer robot 120 and the cooling parts 130 and 140 is achieved by the sliding movement of the hand 121 and the upward and downward movement of the transfer robot 120.

The alignment part 230 is provided on and connected to one side (the positive Y side) of the indexer part 101 in adjacent relation thereto along the Y axis. The alignment part 230 is a processing part for rotating a semiconductor wafer W in a horizontal plane to an orientation appropriate for flash heating. The alignment part 230 includes an alignment chamber 231 which is a housing made of an aluminum alloy, a mechanism provided in the alignment chamber 231 and for supporting and rotating a semiconductor wafer W in a horizontal attitude, a mechanism provided in the alignment chamber 231 and for optically detecting a notch, an orientation flat, and the like formed in a peripheral portion of a semiconductor wafer W, and the like.

The transfer robot 120 transfers a semiconductor wafer W to and from the alignment part 230. The semiconductor wafer W is transferred from the transfer robot 120 to the alignment chamber 231 so that the center of the semiconductor wafer W is positioned at a predetermined position. The alignment part 230 rotates the semiconductor wafer W received from the indexer part 101 about a vertical axis passing through the central portion of the semiconductor wafer W to optically detect a notch and the like, thereby adjusting the orientation of the semiconductor wafer W. The semiconductor wafer W subjected to the orientation adjustment is taken out of the alignment chamber 231 by the transfer robot 120.

The flaw detection part 300 is provided on and connected to the opposite side (the negative Y side) of the indexer part 101 from the alignment part 230 in adjacent relation thereto along the Y axis. The flaw detection part 300 detects the presence or absence of flaws in the back surface of a semiconductor wafer W. One of the main surfaces of the semiconductor wafer W which is patterned and to be treated is a front surface, and the other main surface opposite the front surface is the back surface. The flaw detection part 300 includes a flaw detection chamber 301 which is a housing made of an aluminum alloy, an imaging part provided in the flaw detection chamber 301 and for imaging the back surface of the semiconductor wafer W, a determination part for determining the presence or absence of flaws by performing predetermined image processing on acquired image data, and the like.

The transfer robot 120 transfers a semiconductor wafer W to and from the flaw detection part 300. The semiconductor wafer W is transferred from the transfer robot 120 to the flaw detection chamber 301 so that the center of the semiconductor wafer W is positioned at a predetermined position. In the flaw detection part 300, the back surface of the semiconductor wafer W is imaged, and the presence or absence of flaws is detected by analyzing the obtained image data. The semiconductor wafer W subjected to the flaw detection is taken out of the flaw detection chamber 301 by the transfer robot 120.

A transport chamber 170 for housing the transport robot 150 therein is provided as space for transport of the semiconductor wafer W by means of the transport robot 150. A treatment chamber 6 in the heat treatment part 160, a first cool chamber 131 in the cooling part 130, and a second cool chamber 141 in the cooling part 140 are connected in communication with three sides of the transport chamber 170.

The heat treatment part 160 which is a principal part of the heat treatment apparatus 100 is a substrate processing part for irradiating a preheated semiconductor wafer W with flashes of light from xenon flash lamps FL to perform flash heating treatment on the semiconductor wafer W. The configuration of the heat treatment part 160 will be described later in detail.

The two cooling parts 130 and 140 are substantially similar in configuration to each other. The cooling parts 130 and 140 include respective metal cooling plates and respective quartz plates (both not shown) placed on the upper surfaces of the cooling plates in the first and second cool chambers 131 and 141 which are housings made of an aluminum alloy. Each of the cooling plates is temperature-controlled at ordinary temperatures (approximately 23° C.) by a Peltier element or by circulation of constant-temperature water. The semiconductor wafer W subjected to the flash heating treatment in the heat treatment part 160 is transported into the first cool chamber 131 or the second cool chamber 141, and is then placed and cooled on a corresponding one of the quartz plate.

The first cool chamber 131 and the second cool chamber 141 provided between the indexer part 101 and the transport chamber 170 are connected to both the indexer part 101 and the transport chamber 170. Each of the first cool chamber 131 and the second cool chamber 141 has two openings for transporting the semiconductor wafer W thereinto and therefrom. One of the openings of the first cool chamber 131 which is connected to the indexer part 101 is openable and closable by a gate valve 181. The other opening of the first cool chamber 131 which is connected to the transport chamber 170 is openable and closable by a gate valve 183. In other words, the first cool chamber 131 and the indexer part 101 are connected to each other through the gate valve 181, and the first cool chamber 131 and the transport chamber 170 are connected to each other through the gate valve 183.

The gate valve 181 is opened when the semiconductor wafer W is transferred between the indexer part 101 and the first cool chamber 131. The gate valve 183 is opened when the semiconductor wafer W is transferred between the first cool chamber 131 and the transport chamber 170. When the gate valve 181 and the gate valve 183 are closed, the interior of the first cool chamber 131 is an enclosed space.

One of the two openings of the second cool chamber 141 which is connected to the indexer part 101 is openable and closable by a gate valve 182. The other opening of the second cool chamber 141 which is connected to the transport chamber 170 is openable and closable by a gate valve 184. In other words, the second cool chamber 141 and the indexer part 101 are connected to each other through the gate valve 182, and the second cool chamber 141 and the transport chamber 170 are connected to each other through the gate valve 184.

The gate valve 182 is opened when the semiconductor wafer W is transferred between the indexer part 101 and the second cool chamber 141. The gate valve 184 is opened when the semiconductor wafer W is transferred between the second cool chamber 141 and the transport chamber 170. When the gate valve 182 and the gate valve 184 are closed, the interior of the second cool chamber 141 is an enclosed space.

The cooling parts 130 and 140 further include respective gas supply mechanisms for supplying clean nitrogen gas to the first and second cool chambers 131 and 141 and respective exhaust mechanisms for exhausting atmospheres from the first and second cool chambers 131 and 141. The gas supply mechanisms and the exhaust mechanisms may be capable of changing the flow rates thereof in two levels.

The transport robot 150 provided in the transport chamber 170 is pivotable about a vertical axis as indicated by an arrow 150R. The transport robot 150 includes two linkage mechanisms comprised of a plurality of arm segments. Transport hands 151a and 151b each for holding a semiconductor wafer W are provided at respective distal ends of the two linkage mechanisms. These transport hands 151a and 151b are vertically spaced a predetermined distance apart from each other, and are independently linearly slidable in the same horizontal direction by the respective linkage mechanisms. The transport robot 150 moves a base provided with the two linkage mechanisms upwardly and downwardly to thereby move the two transport hands 151a and 151b spaced the predetermined distance apart from each other upwardly and downwardly.

When the transport robot 150 transfers (loads and unloads) a semiconductor wafer W to and from the first cool chamber 131, the second cool chamber 141, or the treatment chamber 6 in the heat treatment part 160 as a transfer target, both of the transport hands 151a and 151b pivot into opposed relation to the transfer target, and move upwardly or downwardly after (or during) the pivotal movement, so that one of the transport hands 151a and 151b reaches a vertical position at which the semiconductor wafer W is to be transferred to and from the transfer target. Then, the transport robot 150 causes the transport hand 151a (or 151b) to linearly slide in a horizontal direction, thereby transferring the semiconductor wafer W to and from the transfer target.

The transfer of a semiconductor wafer W between the transport robot 150 and the transfer robot 120 is performed through the cooling parts 130 and 140. That is, the first cool chamber 131 in the cooling part 130 and the second cool chamber 141 in the cooling part 140 function also as paths for transferring a semiconductor wafer W between the transport robot 150 and the transfer robot 120. Specifically, one of the transport robot 150 and the transfer robot 120 transfers a semiconductor wafer W to the first cool chamber 131 or the second cool chamber 141, and the other of the transport robot 150 and the transfer robot 120 receives the semiconductor wafer W, whereby the transfer of the semiconductor wafer W is performed. The transport robot 150 and the transfer robot 120 constitute a transport mechanism for transporting a semiconductor wafer W from the carriers C to the heat treatment part 160.

As mentioned above, the gate valves 181 and 182 are provided between the indexer part 101 and the first and second cool chambers 131 and 141, respectively. The gate valves 183 and 184 are provided between the transport chamber 170 and the first and second cool chambers 131 and 141, respectively. A gate valve 185 is further provided between the transport chamber 170 and the treatment chamber 6 of the heat treatment part 160. These gate valves 181 to 185 are opened and closed, as appropriate, when the semiconductor wafer W is transported in the heat treatment apparatus 100. Nitrogen gas is supplied from a gas supply part to the transport chamber 170, the alignment chamber 231, and the flaw detection chamber 301, and an exhaust part exhausts atmospheres from the transport chamber 170, the alignment chamber 231, and the flaw detection chamber 301 (both not shown).

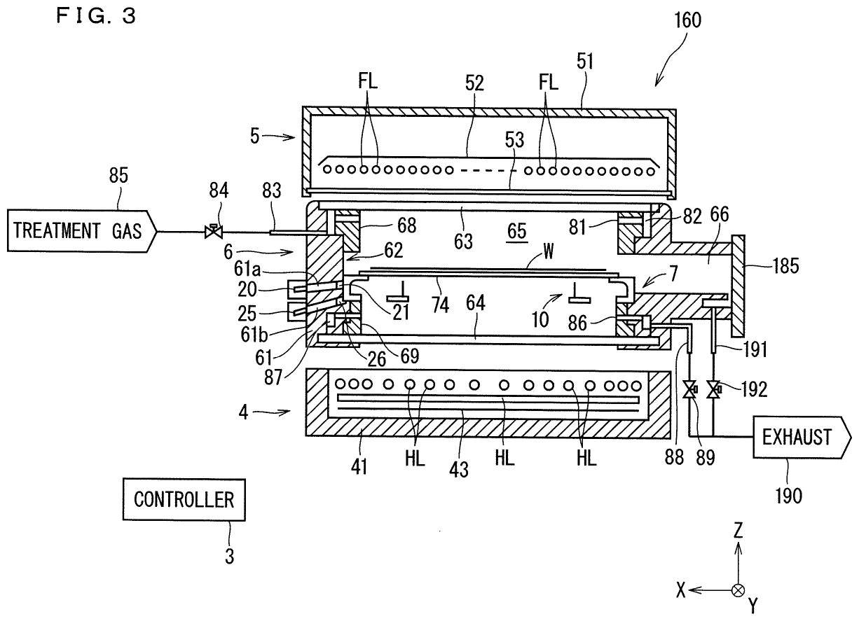

Next, the configuration of the heat treatment part 160 will be described. FIG. 3 is a longitudinal sectional view showing the configuration of the heat treatment part 160. The heat treatment part 160 includes the treatment chamber 6 for receiving a semiconductor wafer W therein to perform heating treatment on the semiconductor wafer W, a flash lamp house 5 including the plurality of built-in flash lamps FL, and a halogen lamp house 4 including a plurality of built-in halogen lamps HL. The flash lamp house 5 is provided over the treatment chamber 6, and the halogen lamp house 4 is provided under the treatment chamber 6. The heat treatment part 160 further includes a holder 7 provided inside the treatment chamber 6 and for holding a semiconductor wafer W in a horizontal attitude, and a transfer mechanism 10 provided inside the treatment chamber 6 and for transferring a semiconductor wafer W between the holder 7 and the transport robot 150.

The treatment chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the treatment chamber 6 is a disk-shaped member made of quartz, and serves as a quartz window that transmits flashes of light emitted from the flash lamps FL therethrough into the treatment chamber 6. The lower chamber window 64 forming the floor of the treatment chamber 6 is also a disk-shaped member made of quartz, and serves as a quartz window that transmits light emitted from the halogen lamps HL therethrough into the treatment chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the treatment chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the treatment chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the treatment chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (substrate carry-in/out opening) 66 for the transport of a semiconductor wafer W therethrough into and out of the treatment chamber 6. The transport opening 66 is openable and closable by the gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the treatment chamber 6 is an enclosed space.

The chamber side portion 61 is further provided with a through hole 61a and a through hole 61b both bored therein. An edge radiation thermometer (edge pyrometer) 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the edge radiation thermometer 20. A center radiation thermometer (center pyrometer) 25 is mounted in a location of the outer wall surface of the chamber side portion 61 where the through hole 61b is provided. The through hole 61b is a cylindrical hole for directing infrared light emitted from the susceptor 74 therethrough to the center radiation thermometer 25. The through holes 61a and 61b are inclined with respect to a horizontal direction so that the longitudinal axes (axes extending in respective directions in which the through holes 61a and 61b extend through the chamber side portion 61) of the respective through holes 61a and 61b intersect the main surfaces of the semiconductor wafer W held by the susceptor 74. Thus, the edge radiation thermometer 20 and the center radiation thermometer 25 are provided obliquely below the susceptor 74. A transparent window 21 and a transparent window 26 both made of barium fluoride material transparent to infrared light in a wavelength range measurable by the edge radiation thermometer 20 and the center radiation thermometer 25 are mounted to an end portion of the through hole 61a and an end portion of the through hole 61b, respectively, which face the heat treatment space 65.

At least one gas supply opening 81 for supplying a treatment gas therethrough into the heat treatment space 65 is provided in an upper portion of the inner wall of the treatment chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the treatment chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and a mixture of these gases (although nitrogen is used in the present preferred embodiment).

At least one gas exhaust opening 86 for exhausting a gas from the heat treatment space 65 is provided in a lower portion of the inner wall of the treatment chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the treatment chamber 6. The gas exhaust pipe 88 is connected to an exhaust mechanism 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the treatment chamber 6, and may be in the form of slits. The treatment gas supply source 85 and the exhaust mechanism 190 may be mechanisms provided in the heat treatment apparatus 100 or be utility systems in a factory in which the heat treatment apparatus 100 is installed.

A gas exhaust pipe 191 for exhausting the gas from the heat treatment space 65 is also connected to a distal end of the transport opening 66. The gas exhaust pipe 191 is connected through a valve 192 to the exhaust mechanism 190. By opening the valve 192, the gas in the treatment chamber 6 is exhausted through the transport opening 66.

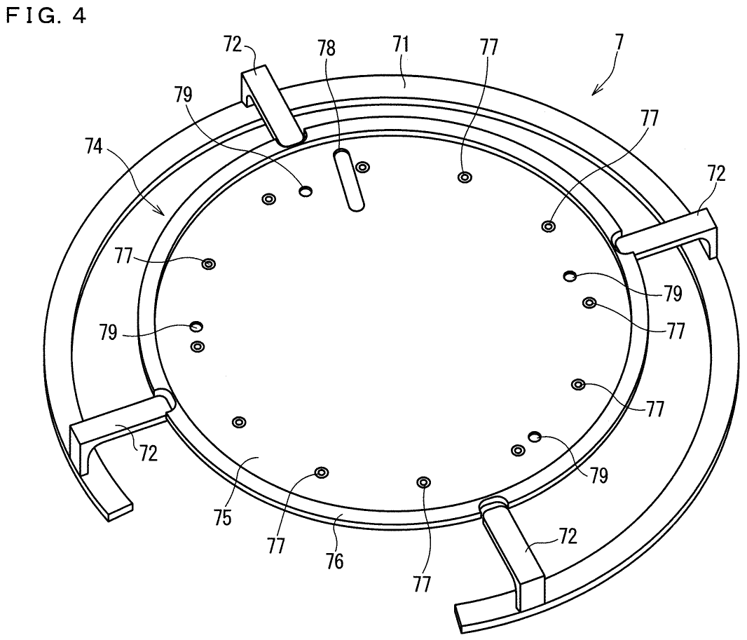

FIG. 4 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the treatment chamber 6 by being placed on the bottom surface of the recessed portion 62 (with reference to FIG. 3). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

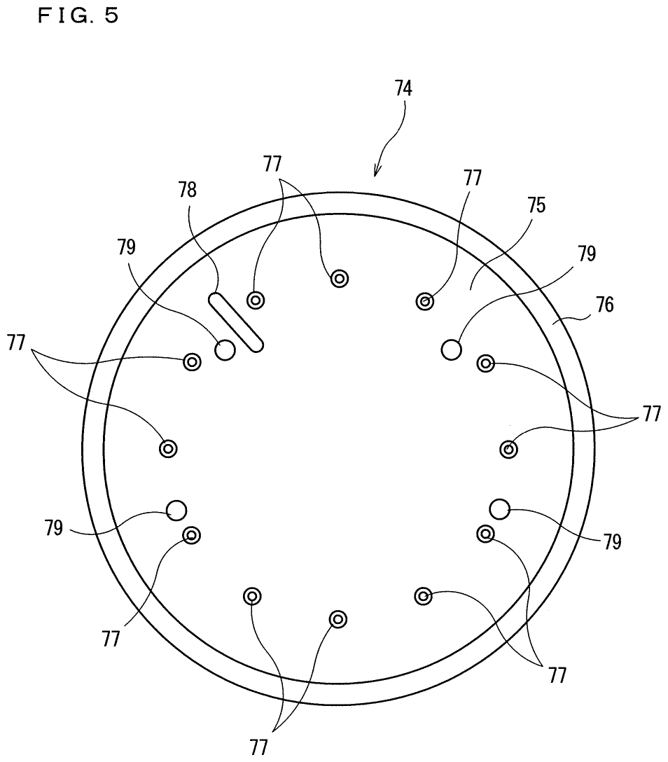

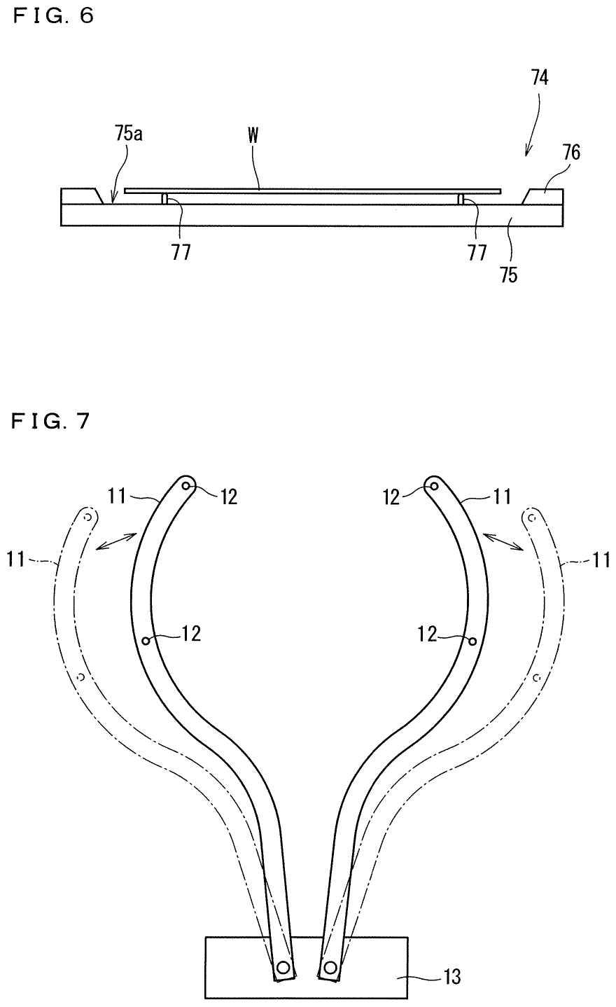

The susceptor 74 is supported by the four coupling portions 72 provided on the base ring 71. FIG. 5 is a plan view of the susceptor 74. FIG. 6 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 4, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the treatment chamber 6, whereby the holder 7 is mounted to the treatment chamber 6. With the holder 7 mounted to the treatment chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the treatment chamber 6 is placed and held in a horizontal attitude on the susceptor 74 of the holder 7 mounted to the treatment chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 4 and 5, an opening 78 is provided in the holding plate 75 of the susceptor 74 so as to extend vertically through the holding plate 75 of the susceptor 74. The opening 78 is provided for the edge radiation thermometer 20 (with reference to FIG. 3) to receive radiation (infrared radiation) emitted from the lower surface of the semiconductor wafer W held by the susceptor 74. Specifically, the edge radiation thermometer 20 receives the radiation emitted from the lower surface of the semiconductor wafer W held by the susceptor 74 through the opening 78 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

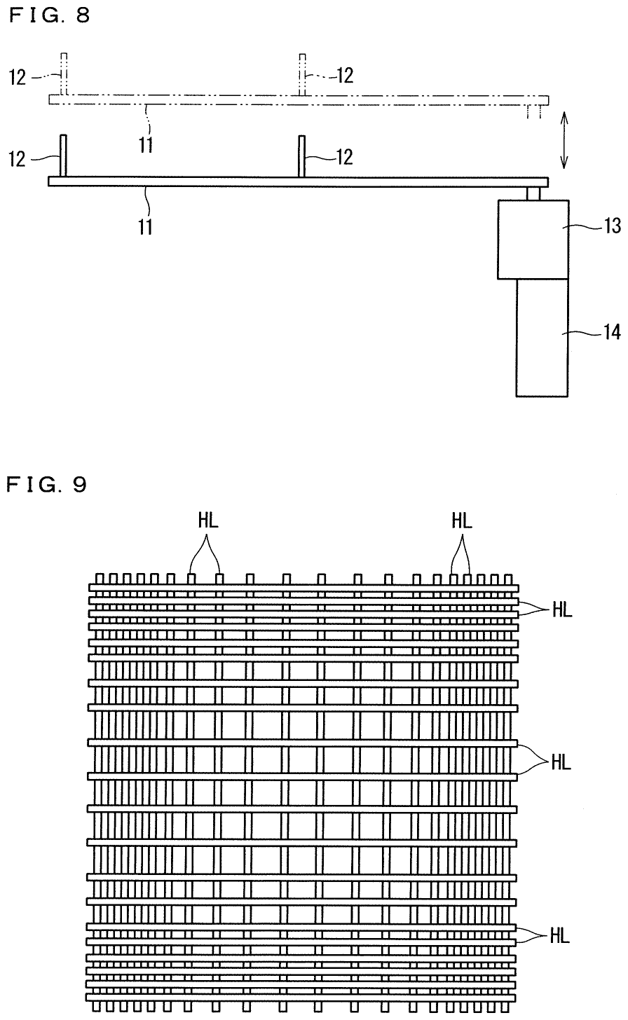

FIG. 7 is a plan view of the transfer mechanism 10. FIG. 8 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 are pivotable by a horizontal movement mechanism 13. The horizontal movement mechanism 13 moves the pair of transfer arms 11 horizontally between a transfer operation position (a position indicated by solid lines in FIG. 7) in which a semiconductor wafer W is transferred to and from the holder 7 and a retracted position (a position indicated by dash-double-dot lines in FIG. 7) in which the transfer arms 11 do not overlap the semiconductor wafer W held by the holder 7 as seen in plan view. The transfer operation position is under the susceptor 74, and the retracted position is outside the susceptor 74. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 4 and 5) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the treatment chamber 6.

As shown in FIG. 3, the treatment chamber 6 includes the two radiation thermometers: the edge radiation thermometer 20 and the center radiation thermometer 25. Both the edge radiation thermometer 20 and the center radiation thermometer 25 are provided below the semiconductor wafer W held by the susceptor 74. The edge radiation thermometer 20 receives the infrared radiation emitted from the lower surface of the semiconductor wafer W through the opening 78 that is a notch provided in the susceptor 74 to measure the temperature of the lower surface of the semiconductor wafer W. In other words, the measurement region of the edge radiation thermometer 20 is inside the opening 78. On the other hand, the measurement region of the center radiation thermometer 25 is in the plane of the holding plate 75 of the susceptor 74. The center radiation thermometer 25 receives the infrared radiation emitted from the susceptor 74 to measure the temperature of the susceptor 74.

The flash lamp house 5 provided over the treatment chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash lamp house 5 further includes a lamp light radiation window 53 mounted to the bottom of the enclosure 51. The lamp light radiation window 53 forming the floor of the flash lamp house 5 is a plate-like quartz window made of quartz. The flash lamp house 5 is provided over the treatment chamber 6, whereby the lamp light radiation window 53 is opposed to the upper chamber window 63. The flash lamps FL direct flashes of light from over the treatment chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen lamp house 4 provided under the treatment chamber 6 includes an enclosure 41 incorporating the multiple (in the present preferred embodiment, 40) halogen lamps HL. The halogen lamps HL direct light from under the treatment chamber 6 through the lower chamber window 64 toward the heat treatment space 65.

FIG. 9 is a plan view showing an arrangement of the multiple halogen lamps HL. In the present preferred embodiment, 20 halogen lamps HL are arranged in each of two tiers, i.e. upper and lower tiers. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 9, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen lamps HL.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the halogen lamps HL arranged in the upper tier and the longitudinal direction of the halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen lamp house 4 under the halogen lamps HL arranged in two tiers (FIG. 3). The reflector 43 reflects the light emitted from the halogen lamps HL toward the heat treatment space 65.

The heat treatment part 160 further includes, in addition to the aforementioned components, various cooling structures to prevent an excessive temperature rise in the halogen lamp house 4, the flash lamp house 5, and the treatment chamber 6 because of the heat energy generated from the halogen lamps HL and the flash lamps FL during the heat treatment of a semiconductor wafer W. As an example, a water cooling tube (not shown) is provided in the walls of the treatment chamber 6. Also, the halogen lamp house 4 and the flash lamp house 5 have an air cooling structure for forming a gas flow therein to exhaust heat. Air is supplied to a gap between the upper chamber window 63 and the lamp light radiation window 53 to cool down the flash lamp house 5 and the upper chamber window 63.

The controller 3 controls the aforementioned various operating mechanisms provided in the heat treatment apparatus 100. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 100 proceed. The controller 3 is shown in the indexer part 101 in FIG. 1. The present invention, however, is not limited to this. The controller 3 may be disposed in any position in the heat treatment apparatus 100.

Next, a processing operation in the heat treatment apparatus 100 according to the present invention will be described. First, a processing operation for a semiconductor wafer (product wafer) W that becomes a product will be described. A procedure for processing of the semiconductor wafer W which will be described below proceeds under the control of the controller 3 over the operating mechanisms of the heat treatment apparatus 100.

First, while being stored in a carrier C, untreated semiconductor wafers W are placed on the first load port 110a or the second load port 110b of the indexer part 101. The transfer robot 120 takes the untreated semiconductor wafers W one by one out of the carrier C to transport each of the untreated semiconductor wafers W into the alignment chamber 231 of the alignment part 230. In the alignment chamber 231, a semiconductor wafer W is rotated in a horizontal plane about a vertical axis passing through the central portion of the semiconductor wafer W, and a notch or the like is optically detected, whereby the orientation of the semiconductor wafer W is adjusted.

Next, the transfer robot 120 of the indexer part 101 takes the orientation-adjusted semiconductor wafer W out of the alignment chamber 231 to transport the semiconductor wafer W into the flaw detection chamber 301 of the flaw detection part 300. In the flaw detection chamber 301, the back surface of the semiconductor wafer W is imaged, and the presence or absence of flaws is detected by analyzing the obtained image data. A semiconductor wafer W in which any flaw is detected may be returned to the carrier C because there is a danger that the semiconductor wafer W is cracked when irradiated with a flash of light in the heat treatment part 160.

Next, the transfer robot 120 takes the semiconductor wafer W out of the flaw detection chamber 301 to transport the semiconductor wafer W into the first cool chamber 131 of the cooling part 130 or the second cool chamber 141 of the cooling part 140. The untreated semiconductor wafer W transported into the first cool chamber 131 or the second cool chamber 141 is transported to the transport chamber 170 by the transport robot 150. The first cool chamber 131 and the second cool chamber 141 function as the paths for transferring the semiconductor wafer W when the untreated semiconductor wafer W is transferred from the indexer part 101 via the first cool chamber 131 or the second cool chamber 141 to the transport chamber 170.

After taking out the semiconductor wafer W, the transport robot 150 pivots so as to face toward the heat treatment part 160. Subsequently, the transport robot 150 transports the untreated semiconductor wafer W into the treatment chamber 6 of the heat treatment part 160.

The semiconductor wafer W transported into the treatment chamber 6 is preheated by the halogen lamps HL, and is thereafter subjected to the flash heating treatment by flash irradiation from the flash lamps FL. This flash heating treatment activates the impurities implanted in the semiconductor wafer W, for example.

After the completion of the flash heating treatment, the transport robot 150 transports the semiconductor wafer W subjected to the flash heating treatment from the treatment chamber 6 to the transport chamber 170. After taking out the semiconductor wafer W, the transport robot 150 pivots from the treatment chamber 6 so as to face toward the first cool chamber 131 or the second cool chamber 141.

Thereafter, the transport robot 150 transports the semiconductor wafer W subjected to the heating treatment into the first cool chamber 131 of the cooling part 130 or the second cool chamber 141 of the cooling part 140. At this time, the semiconductor wafer W that has passed through the first cool chamber 131 before the heating treatment is also transported into the first cool chamber 131 after the heating treatment, and the semiconductor wafer W that has passed through the second cool chamber 141 before the heating treatment is also transported into the second cool chamber 141 after the heating treatment. In the first cool chamber 131 or the second cool chamber 141, the semiconductor wafer W subjected to the flash heating treatment is cooled. The semiconductor wafer W is cooled to near room temperatures in the first cool chamber 131 or the second cool chamber 141 because the temperature of the entire semiconductor wafer W is relatively high when the semiconductor wafer W is transported out of the treatment chamber 6 of the heat treatment part 160.

After a lapse of a predetermined cooling time period, the transfer robot 120 transports the cooled semiconductor wafer W out of the first cool chamber 131 or the second cool chamber 141, and returns the cooled semiconductor wafer W back to the carrier C. After a predetermined number of treated semiconductor wafers W are stored in the carrier C, the carrier C is transported from the first load port 110a or the second load port 110b of the indexer part 101 to the outside.

The description on the heating treatment in the heat treatment part 160 will be continued. Prior to the transport of the semiconductor wafer W into the treatment chamber 6, the valve 84 for supply of gas is opened, and the valves 89 and 192 for exhaust of gas are opened, so that the supply and exhaust of gas into and out of the treatment chamber 6 start. When the valve 84 is opened, nitrogen gas is supplied through the gas supply opening 81 into the heat treatment space 65. When the valve 89 is opened, the gas within the treatment chamber 6 is exhausted through the gas exhaust opening 86. This causes the nitrogen gas supplied from an upper portion of the heat treatment space 65 in the treatment chamber 6 to flow downwardly and then to be exhausted from a lower portion of the heat treatment space 65.

The gas within the treatment chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment part 160. The amount of nitrogen gas supplied into the heat treatment space 65 is changed as appropriate in accordance with process steps.

Subsequently, the gate valve 185 is opened to open the transport opening 66. The transport robot 150 transports a semiconductor wafer W to be treated through the transport opening 66 into the heat treatment space 65 of the treatment chamber 6. The transport robot 150 moves the transport hand 151a (or the transport hand 151b) holding the untreated semiconductor wafer W forward to a position lying immediately over the holder 7, and stops the transport hand 151a (or the transport hand 151b) thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the untreated semiconductor wafer W is placed on the lift pins 12, the transport robot 150 causes the transport hand 151a to move out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface to be heat-treated is the upper surface. A predetermined distance is defined between the back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7, the 40 halogen lamps HL turn on simultaneously to start preheating (or assist-heating). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the edge radiation thermometer 20 when the halogen lamps HL perform the preheating. Specifically, the edge radiation thermometer 20 receives infrared radiation emitted from the lower surface of the semiconductor wafer W held by the susceptor 74 through the opening 78 to measure the temperature of the semiconductor wafer W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the edge radiation thermometer 20. The preheating temperature T1 is on the order of 600° to 800° C., for example.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the edge radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in a peripheral portion thereof where heat dissipation is liable to occur than in a central portion thereof. However, the halogen lamps HL in the halogen lamp house 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating.

The flash lamps FL irradiate the front surface of the semiconductor wafer W with a flash of light at the point in time when a predetermined time period has elapsed since the temperature of the semiconductor wafer W reached the preheating temperature T1. At this time, part of the flash of light emitted from the flash lamps FL travels directly toward the interior of the treatment chamber 6. The remainder of the flash of light is reflected once from the reflector 52, and then travels toward the interior of the treatment chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2, and thereafter decreases rapidly. The treatment temperature T2 is 1000° C. or higher, for example. In this manner, the flash heating is able to increase and decrease the front surface temperature of the semiconductor wafer W in an extremely short time. This achieves the activation of the impurities implanted in the semiconductor wafer W while suppressing the diffusion of the impurities due to heat, for example.

After a predetermined time period has elapsed since the completion of the flash heating treatment, the halogen lamps HL turn off. This causes the temperature of the semiconductor wafer W to decrease rapidly from the preheating temperature T1. The edge radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the edge radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport hand 151b (or the transport hand 151a) of the transport robot 150 transports the treated semiconductor wafer W placed on the lift pins 12 to the outside. The transport robot 150 moves the transport hand 151b forward to a position lying immediately under the semiconductor wafer W thrust upwardly by the lift pins 12, and stops the transport hand 151b thereat. Then, the pair of transfer arms 11 moves downwardly, whereby the semiconductor wafer W subjected to the flash heating is transferred to and placed on the transport hand 151b. Thereafter, the transport robot 150 causes the transport hand 151b to move out of the treatment chamber 6, thereby transporting the treated semiconductor wafer W to the outside.

In the present preferred embodiment, a semiconductor wafer W sent out from a carrier C placed on the load port 110 is subjected to the orientation adjustment in the alignment part 230 and the flaw detection in the flaw detection part 300 and is then transported to the treatment chamber 6 of the heat treatment part 160. Thus, the time required for the transport of the semiconductor wafer W from the carrier C to the treatment chamber 6 in the present preferred embodiment is longer than that in the conventional configuration as disclosed, for example, in U.S. Patent Application Publication No. 2020/0243357 by the amount of processing time in the flaw detection part 300. As a result, whereas the exchange of heat-treated and untreated semiconductor wafers W has been conventionally performed using the transport hands 151a and 151b of the transport robot 150 in the treatment chamber 6, there arise cases in which the wafer exchange cannot be performed due to the prolongation of the transport time of the semiconductor wafer W. Specifically, when the heat treatment of a preceding semiconductor wafer (a first substrate) W1 is completed in the treatment chamber 6, a succeeding untreated semiconductor wafer (a second substrate) W2 has not reached the treatment chamber 6 in some cases due to the prolongation of the transport time.

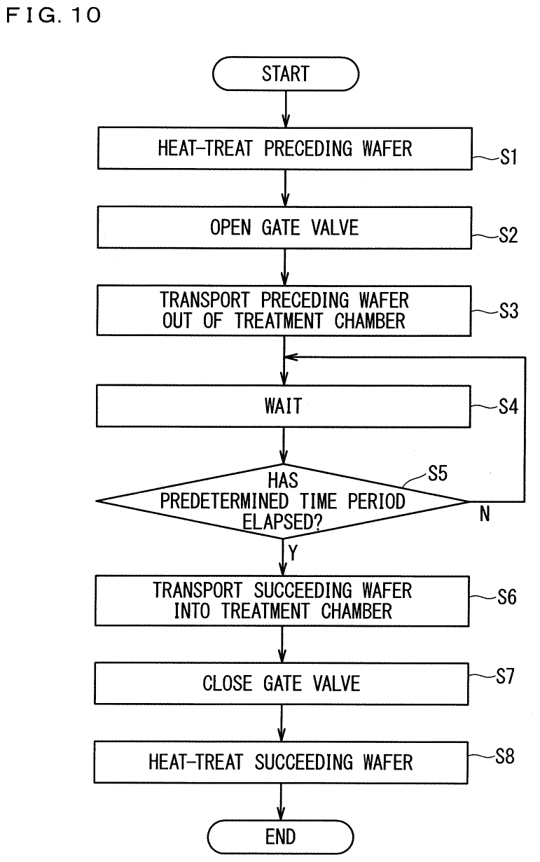

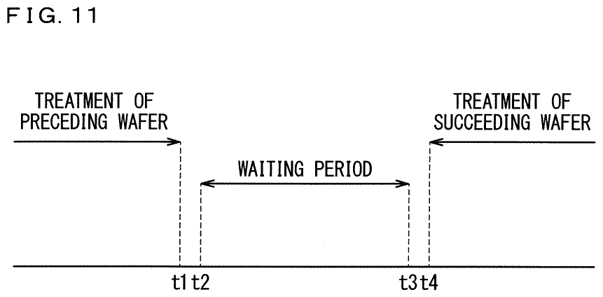

To prevent this, the present preferred embodiment exchanges the preceding semiconductor wafer W1 (referred to hereinafter as a “preceding wafer W1”) and the succeeding semiconductor wafer W2 (referred to hereinafter as a “succeeding wafer W2”) in a manner to be described below. FIG. 10 is a flow diagram showing a procedure for the wafer exchange in the first preferred embodiment. FIG. 11 is a timing diagram of the wafer exchange.

First, the preceding wafer W1 is heat-treated in the treatment chamber 6 of the heat treatment part 160 (Step S1). The heat treatment of the preceding wafer W1 in the treatment chamber 6 is as described above, and is performed in accordance with a previously created recipe. Thus, the heat treatment time of the preceding wafer W1 in the treatment chamber 6 is as specified in the recipe. The recipe refers to a specification of the heat treatment procedure and heat treatment conditions for semiconductor wafers W.

The gate valve 185 opens the transport opening 66 (Step S2) at time t1 when the heat treatment of the preceding wafer W1 specified in the recipe is completed in the treatment chamber 6, specifically when a predetermined time period has elapsed since the lift pins 12 moved upwardly to receive the heated preceding wafer W1. It should be noted that the predetermined time period after the upward movement of the lift pins 12 is the time required to decrease the temperature of the preceding wafer W1, which is at a high temperature immediately after the heating, to such a degree that the transport robot 150 is able to contact the preceding wafer W1.

After the gate valve 185 is opened, the transport robot 150 uses the transport hand 151b to transport the preceding wafer W1 out of the treatment chamber 6 at time t2 (Step S3). At this time, the transport robot 150 does not transport the succeeding wafer W2 into the treatment chamber 6, regardless of whether the other transport hand 151a holds the untreated succeeding wafer W2 or not. In other words, the simultaneous exchange of the preceding wafer W1 and the succeeding wafer W2 is not performed at the time t2.

After the preceding wafer W1 is transported out of the treatment chamber 6, a wait of a predetermined time period starts, with no semiconductor wafer W present in the treatment chamber 6 (Steps S4 and S5). In the first preferred embodiment, the mechanisms in the heat treatment part 160 stop operating during the waiting period. Specifically, both the flash lamps FL and the halogen lamps HL are off during the waiting period. However, the nitrogen gas may be supplied to the treatment chamber 6. Also, mechanisms other than the heat treatment part 160 provided in the heat treatment apparatus 100 may continue to operate during the waiting period. For example, the transfer robot 120 and the transport robot 150 may operate during the waiting period. In the first preferred embodiment, the gate valve 185 may remain open during the waiting period.

At time t3 when the predetermined waiting time period has elapsed, the transport robot 150 uses the transport hand 151a to transport the succeeding wafer W2 into the treatment chamber 6 (Step S6). This completes the waiting period, and the preceding wafer W1 and the succeeding wafer W2 are exchanged at a fixed time interval. The waiting time period from the time t2 to the time t3 is, for example, 15 seconds. This waiting time period is previously set as an apparatus parameter and stored, for example, in the storage part of the controller 3.

Next, after the transport robot 150 causes the empty transport hand 151a to move out of the treatment chamber 6, the gate valve 185 closes the transport opening 66 (Step S7). Subsequently, at time t4, the heat treatment of the succeeding wafer W2 starts in the treatment chamber 6 (Step S8). The heat treatment of the succeeding wafer W2 is the same as that of the preceding wafer W1, and is performed in accordance with the aforementioned recipe.

In the first preferred embodiment, the succeeding wafer W2 is not transported into the treatment chamber 6 at the same time that the heat-treated preceding wafer W1 is transported out of the treatment chamber 6, but is transported into the treatment chamber 6 after the wait of the fixed time period. Thus, the time from the start of the heat treatment of the preceding wafer W1 to the start of the heat treatment of the succeeding wafer W2, i.e., the cycle time for the preceding wafer W1 is extended to ta+tb which is the sum of a treatment time period ta specified in the recipe (e.g., 60 seconds) and the aforementioned waiting time period tb (e.g., 15 seconds). This means that the treatment time period of the preceding wafer W1 is extended by the waiting time period tb to virtually become ta+tb. Even if the preceding wafer W1 is kept in the treatment chamber 6 without being transported out of the treatment chamber 6 at the time t2 but is transported out of the treatment chamber 6 at the time t3 and exchanged for the succeeding wafer W2, the treatment time period will still be ta+tb. However, keeping the heat-treated semiconductor wafer W in the treatment chamber 6 that is at a high temperature affects the properties of the semiconductor wafer W. For this reason, the preceding wafer W1 is transported out of the treatment chamber 6 at the time t2 as specified in the recipe.

Even if the transport time of the semiconductor wafer W from the carrier C to the treatment chamber 6 is prolonged due to the flaw detection in the flaw detection part 300, the virtually extended treatment time period of the semiconductor wafer W is made longer than the transport time by setting the treatment time period to ta+tb. As a result, the state of chamber rate-determining in which the treatment in the chamber is the rate-determining step is maintained, and the succeeding wafer W2 is transported into the treatment chamber 6 with reliability at the time t3 at which the succeeding wafer W2 is scheduled to be transported into the treatment chamber 6.

In the first preferred embodiment, the temperature in the treatment chamber 6 is lower when the succeeding wafer W2 is transported into the treatment chamber 6 at the time t3 than when the preceding wafer W1 is transported out of the treatment chamber 6 at the time t2 because the temperature in the treatment chamber 6 decreases during the waiting period. However, since the time (=the waiting time period tb) from the transport of the preceding wafer W1 out of the treatment chamber 6 to the transport of the succeeding wafer W2 into the treatment chamber 6 is constant for all semiconductor wafers (strictly speaking, the second and subsequent semiconductor wafers) in a lot, the degree of temperature decrease is also constant, and the treatment conditions of the semiconductor wafers W are made uniform.

In short, the first preferred embodiment provides the fixed waiting time period after the transport of the preceding wafer W1 out of the treatment chamber 6, and transports the succeeding wafer W2 into the treatment chamber 6 after a lapse of the waiting time period to virtually extend the treatment time period for the preceding wafer W1, thereby maintaining the state of chamber rate-determining. There is no need to change the treatment time period in the recipe because the waiting time period is an apparatus parameter. In other words, the first preferred embodiment is capable of making the treatment conditions of the semiconductor wafers W uniform without changing the recipe.

### Second Preferred Embodiment

Next, a second preferred embodiment of the present invention will be described. The configurations of the heat treatment apparatus 100 and the heat treatment part 160 in the second preferred embodiment are the same as those in the first preferred embodiment. The procedure for the heating treatment of the semiconductor wafer W in the second preferred embodiment is the same as that in the first preferred embodiment. In the second preferred embodiment, an atmosphere in the treatment chamber 6 is heated during the waiting period for the wafer exchange.

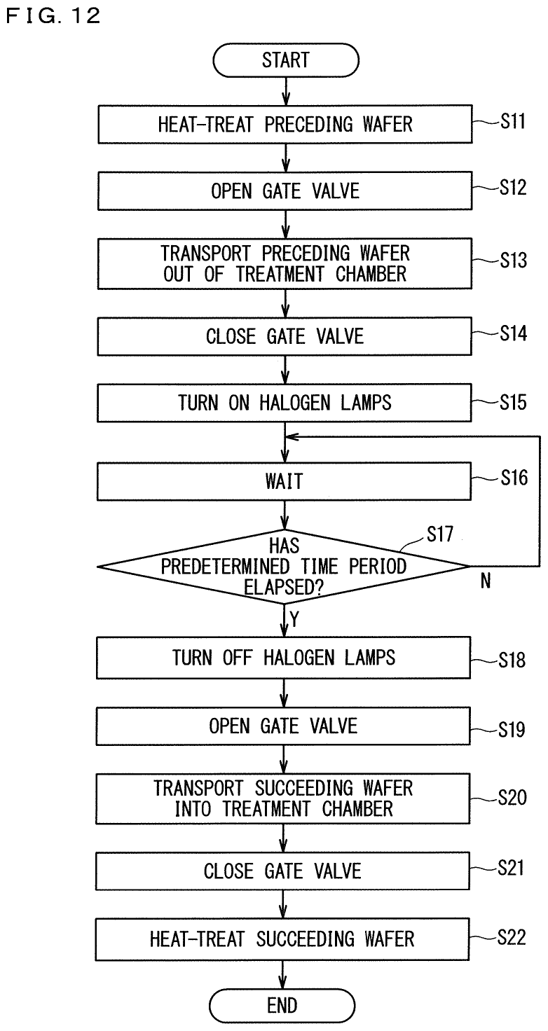

FIG. 12 is a flow diagram showing a procedure for the wafer exchange in the second preferred embodiment. Processes in Steps S11 to S13 are the same as those in Steps S1 to S3 in the first preferred embodiment (FIG. 10). Specifically, the preceding wafer W1 is heat-treated in the treatment chamber 6 of the heat treatment part 160 (Step S11). When the treatment is completed, the gate valve 185 opens the transport opening 66 (Step S12). Subsequently, the transport robot 150 uses the transport hand 151b to transport the preceding wafer W1 out of the treatment chamber 6 (Step S13).

In the second preferred embodiment, once the preceding wafer W1 is transported out of the treatment chamber 6, the gate valve 185 closes the transport opening 66 (Step S14). Then, the halogen lamps HL turn on (Step S15), and a wait of a predetermined time period starts (Steps S16 and S17). In the second preferred embodiment, the halogen lamps HL are on during the waiting period. The light emitted from the halogen lamps HL heats the atmosphere in the treatment chamber 6 either directly or indirectly after being absorbed by the susceptor 74 and the like. That is, the atmosphere in the treatment chamber 6 is heated by light irradiation from the halogen lamps HL during the predetermined waiting time period in the second preferred embodiment. The nitrogen gas may be supplied to the treatment chamber 6 during the waiting period.

The controller 3 effects feedback control (closed-loop control) of the output from the halogen lamps HL so that the temperature of the susceptor 74 is equal to a target value, based on the temperature value of the susceptor 74 measured by the center radiation thermometer 25. For example, a correlation table showing a correlation between the temperature of the susceptor 74 and the temperature of the atmosphere in the treatment chamber 6 is previously created and stored, and the controller 3 is required only to effect the feedback control of the output from the halogen lamps HL so that the temperature of the atmosphere measured when the preceding wafer W1 is transported out of the treatment chamber 6 and the temperature of the atmosphere measured when the succeeding wafer W2 is transported into the treatment chamber 6 are equal to each other. That is, the controller 3 is required only to effect the feedback control of the output from the halogen lamps HL during the waiting period so as to maintain the temperature of the atmosphere measured when the preceding wafer W1 is transported out of the treatment chamber 6.

When the predetermined waiting time period has elapsed, the halogen lamps HL turn off (Step S18), and the gate valve 185 opens the transport opening 66 (Step S19). The subsequent processes in Steps S20 to S22 are the same as those in Steps S6 to S8 in the first preferred embodiment. Specifically, the transport robot 150 uses the transport hand 151a to transport the succeeding wafer W2 into the treatment chamber 6 (Step S20). This causes the preceding wafer W1 and the succeeding wafer W2 to be exchanged at a fixed time interval also in the second preferred embodiment. After the transport robot 150 causes the empty transport hand 151a to move out of the treatment chamber 6, the gate valve 185 closes the transport opening 66 (Step S21). The heat treatment of the succeeding wafer W2 starts in the treatment chamber 6 (Step S22).

Like the first preferred embodiment, the second preferred embodiment also causes the wait of the fixed time period to start after the transport of the preceding wafer W1 out of the treatment chamber 6, and transports the succeeding wafer W2 into the treatment chamber 6 after the completion of the waiting period to virtually extend the treatment time period for the preceding wafer W1, thereby maintaining the state of chamber rate-determining. In addition, the second preferred embodiment heats the atmosphere in the treatment chamber 6 by light irradiation from the halogen lamps HL during the waiting period to thereby maintain the temperature in the treatment chamber 6 at the temperature measured when the preceding wafer W1 is transported out of the treatment chamber 6.

Thus, the temperature in the treatment chamber 6 measured when the succeeding wafer W2 is transported into the treatment chamber 6 is equal to the temperature in the treatment chamber 6 measured when the preceding wafer W1 is transported out of the treatment chamber 6, as in the case where the succeeding wafer W2 is transported into the treatment chamber 6 at the same time that the preceding wafer W1 is transported out of the treatment chamber 6. Preliminary evaluation for creating the aforementioned recipe is based on the assumption that the temperature in the treatment chamber 6 measured when the preceding wafer W1 is transported out of the treatment chamber 6 is equal to the temperature in the treatment chamber 6 measured when the succeeding wafer W2 is transported into the treatment chamber 6 because of the simultaneous exchange of the preceding wafer W1 and the succeeding wafer W2. Thus, the second preferred embodiment is made consistent with the conditions of the preliminary evaluation for all semiconductor wafers W in a lot.

For all semiconductor wafers W in a lot, the temperatures in the treatment chamber 6 measured when the semiconductor wafers W are transported into the treatment chamber 6 are equal. This makes the treatment conditions of the semiconductor wafers W uniform. Further, the second preferred embodiment prevents the temperature in the treatment chamber 6 from decreasing by performing the light irradiation from the halogen lamps HL even during the waiting period over which no semiconductor wafer W is present in the treatment chamber 6. That is, even if the transport time of the semiconductor wafers W is prolonged, the second preferred embodiment prevents the temperature in the treatment chamber 6 from decreasing to make the treatment conditions of the semiconductor wafers W more uniform.

In the second preferred embodiment, the heating is performed by light irradiation from the halogen lamps HL during the waiting period, with the transport opening 66 closed by the gate valve 185. This improves the heating efficiency of the halogen lamps HL. Also, the gate valve 185 closes the transport opening 66 to thereby prevent light emitted from the halogen lamps HL and reflected inside the treatment chamber 6 from leaking out of the transport opening 66.

### Modifications

While the preferred embodiments according to the present invention have been described hereinabove, various modifications of the present invention in addition to those described above may be made without departing from the scope and spirit of the invention. For example, although the gate valve 185 is open during the waiting period in the first preferred embodiment, the gate valve 185 may be closed during the waiting period. On the other hand, although the gate valve 185 is closed during the waiting period in the second preferred embodiment, the gate valve 185 may be open during the waiting period. In the second preferred embodiment in which the halogen lamps HL turn on, it is however preferable to keep the gate valve 185 closed during the waiting period from the viewpoints of improvement in heating efficiency and safety.

In the second preferred embodiment, if a dummy wafer DW is allowed to be transported into the transport robot 150, the dummy wafer DW may be held by the susceptor 74 and irradiated with light from the halogen lamps HL during the waiting period. The dummy wafer DW is a disk-shaped silicon wafer similar to the semiconductor wafers W that become products, and is similar in size and shape to the semiconductor wafers W. This causes the dummy wafer DW to absorb the light emitted from the halogen lamps HL, thereby increasing the temperature of the dummy wafer DW. As a result, the atmosphere in the treatment chamber 6 is heated more efficiently by heat conduction from the dummy wafer DW that is increased in temperature.

Although the controller 3 effects the feedback control of the output from the halogen lamps HL in the second preferred embodiment, the controller 3 may effect open-loop control of the output from the halogen lamps HL instead. For the open-loop control, the output from the halogen lamps HL may be set to a low output so that the temperature of the atmosphere in the treatment chamber 6 does not increase to an excessively high temperature (because the excessively high temperature in the treatment chamber 6 causes the transport of the succeeding wafer W2 into the treatment chamber 6 that is higher in temperature than the preliminary evaluation, resulting in non-uniform treatment conditions of the semiconductor wafers W).

Although the 30 flash lamps FL are provided in the flash lamp house 5 in the aforementioned preferred embodiments, the present invention is not limited to this. Any number of flash lamps FL may be provided. The flash lamps FL are not limited to the xenon flash lamps, but may be krypton flash lamps. Also, the number of halogen lamps HL provided in the halogen lamp house 4 is not limited to 40. Any number of halogen lamps HL may be provided.

In the aforementioned preferred embodiments, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A method of heating a substrate by irradiating the substrate with light, said method comprising the steps of:
(a) irradiating a first substrate held by a susceptor in a chamber with light from a lamp to heat said first substrate;
(b) transporting said first substrate out of said chamber by means of a transport robot, said step (b) being executed after the completion of said step (a);
(c) waiting for a predetermined time period, with no substrate present in said chamber, said step (c) being executed after said step (b);
(d) transporting a second substrate into said chamber by means of said transport robot; and
(e) irradiating said second substrate held by said susceptor in said chamber with light from said lamp to heat the said second substrate.

2. The method according to claim 1,
wherein an atmosphere in said chamber is heated by the light irradiation from said lamp in said step (c).

3. The method according to claim 2,
wherein an output from said lamp is feedback-controlled based on a measured temperature of said susceptor in said step (c).

4. The method according to claim 2,
wherein a substrate carry-in/out opening of said chamber is closed when the atmosphere in said chamber is heated.

5. A heat treatment apparatus for heating a substrate by irradiating the substrate with light, comprising:
a chamber for receiving a substrate therein;
a susceptor for holding said substrate in said chamber;
a lamp for irradiating said substrate held by said susceptor with light;
a transport robot for transporting said substrate into and out of said chamber; and
a controller for controlling said lamp and said transport robot,
wherein said controller controls said transport robot so that, after said transport robot transports a first substrate subjected to heating treatment by the light irradiation from said lamp out of said chamber, said transport robot waits for a predetermined time period, with no substrate present in said chamber, and then transports a second substrate into said chamber.

6. The heat treatment apparatus according to claim 5,
wherein said lamp heats an atmosphere in said chamber by the light irradiation during the waiting period, with no substrate present in said chamber.

7. The heat treatment apparatus according to claim 6, further comprising
a temperature measurement part for measuring the temperature of said susceptor,
wherein said controller effects feedback control of an output from said lamp, based on the temperature measured by said temperature measurement part.

8. The heat treatment apparatus according to claim 6, further comprising
a gate valve for opening and closing a substrate carry-in/out opening of said chamber,
wherein said gate valve closes said substrate carry-in/out opening when the atmosphere in said chamber is heated.
